(19) United States
(12) Patent Application Publication
(10) Pub. No.: US 2022/0344207 A1
(43) Pub. Date: Oct. 27, 2022

(54) CUTTING METHOD OF WAFER

(71) Applicant: DISCO CORPORATION, Tokyo (JP)

(72) Inventor: Tomoharu TAKITA, Tokyo (JP)

(21) Appl. No.: 17/658,031

(22) Filed: Apr. 5, 2022

(30) Foreign Application Priority Data
Apr. 21, 2021 (JP) 2021-071555

(51) Int. Cl. H01L 21/78; H01L 21/683

(52) U.S. Cl. CPC H01L 21/78; H01L 21/6836

(57) ABSTRACT

There is provided a cutting method of a wafer for cutting the wafer that includes a circular recess part and an annular projection part. The cutting method of a wafer includes a tape sticking step of sticking an adhesive tape along the recess part and the projection part, a holding step of sucking the adhesive tape stuck to the recess part by a holding surface of a chuck table having the holding surface with a smaller diameter than the recess part to hold the wafer by the chuck table with the interposition of the adhesive tape, and a cutting step of separating the recess part and the projection part by making a cutting blade that rotates cut into the wafer and rotating the chuck table in the state in which the projection part is not fixed.

### BACKGROUND OF THE INVENTION

### Field of the Invention

The present invention relates to a cutting method of a wafer.

### Description of the Related Art

In a manufacturing process of device chips, a wafer is used that includes, on a front surface side, a device region in which a device is formed in each of multiple regions marked out by multiple streets (planned dividing lines) arranged in a lattice manner. Multiple device chips each including the device are obtained by dividing this wafer along the streets. The device chips are mounted on various types of electronic equipment, such as portable phones and personal computers.

In recent years, reducing a thickness of the device chips has been required in association with size reduction of electronic equipment. Thus, processing of thinning a wafer is executed before dividing of the wafer in some cases. For the thinning of the wafer, a grinding apparatus is used, for example. The grinding apparatus includes a chuck table that holds a workpiece and a grinding unit that executes grinding processing for the workpiece, and a grinding wheel including grinding abrasive stones is mounted on the grinding unit. The grinding apparatus grinds and thins the wafer by bringing the grinding abrasive stones into contact with a back surface side of the wafer held by the chuck table.

When the wafer is ground and thinned, the rigidity of the wafer lowers and subsequent handling (conveyance, holding, and so forth) of the wafer becomes difficult. Thus, a method in which only the region that overlaps with the device region in the back surface side of a wafer is ground and thinned has been proposed. When this method is used, a recess part is formed at a central part of the wafer, whereas the outer circumferential part of the wafer is not thinned but kept at the thick state and remains as an annular projection part. As a result, the outer circumferential part (projection part) of the wafer functions as a reinforcing part, and the lowering of the rigidity of the wafer after the grinding is suppressed.

The thinned wafer is divided into multiple device chips finally. At this time, the annular projection part that remains at the outer circumferential part of the wafer is removed in advance so as not to hinder the dividing. For the removal of the projection part of the wafer, a cutting apparatus that cuts a workpiece by an annular cutting blade is used, for example. By annularly cutting the wafer by the cutting blade, the central part (recess part) and the outer circumferential part (projection part) of the wafer are separated. When the wafer having the recess part is processed by the cutting apparatus, the wafer is held by a dedicated chuck table mounted in the cutting apparatus. In Japanese Patent Laid-open No. 2013-98248, a chuck table including a raised-up part (projection part) fitted into the recess part of a wafer is disclosed. When the wafer is disposed on this chuck table, the recess part of the wafer is supported by the raised-up part and the outer circumferential part of the wafer is supported by a spacer disposed around the raised-up part. Due to this, the wafer is held in a flat state by the chuck table.

### SUMMARY OF THE INVENTION

In general, it is considered that, in order to properly process the wafer having the recess part by the cutting apparatus, holding the whole of the wafer by the chuck table is indispensable. Furthermore, typically the chuck table including the projection part (raised-up part) corresponding to the recess part of the wafer like the above-described one is used. However, when there is a difference between a depth of the recess part of the wafer and the amount of protrusion (height) of the projection part of the chuck table, the wafer is not flatly held and becomes a bending state, and a local stress is applied in the vicinity of a boundary between the recess part and the outer circumferential part of the wafer in particular. When the wafer is cut by the cutting blade in this state, a processing defect such as chipping (breakage) is liable to occur. For this reason, the projection part of the chuck table is formed in such a manner that the amount of protrusion thereof corresponds with the depth of the recess part of the wafer as far as possible.

However, there is variation in the thickness of the wafer, the depth of the recess part of the wafer, the thickness of a tape (dicing tape) stuck to the wafer, dimensions of the chuck table, and so forth, and there is a limit also on the accuracy of processing for forming the projection part in the chuck table. Because of such various causes, it is difficult to cause the depth of the recess part of the wafer to strictly correspond with the amount of protrusion of the projection part of the chuck table and realistically an error of 10 μm or larger is caused between the two in many cases. As a result, the wafer having the recess part is fixed to the chuck table in a slightly bending state, and the occurrence of a processing defect is not sufficiently suppressed in some cases. Furthermore, the depth of the recess part of the wafer differs according to the kind (diameter, thickness, material, and so forth) of the wafer. Thus, every time the kind of the wafer that becomes the processing target is changed, the amount of protrusion of the projection part of the chuck table also needs to be changed. Due to this, labor and cost are required for preparation and replacement of the chuck table, and the efficiency of processing of the wafer by the cutting apparatus also lowers.

The present invention is made in view of such a problem and intends to provide a cutting method of a wafer that allows proper cutting of the wafer having a recess part.

In accordance with an aspect of the present invention, there is provided a cutting method of a wafer for cutting the wafer that includes a circular recess part at a central part and includes an annular projection part surrounding the recess part at an outer circumferential part. The cutting method of a wafer includes a tape sticking step of sticking an adhesive tape along the recess part and the projection part, a holding step of sucking the adhesive tape stuck to the recess part by a holding surface of a chuck table having the holding surface with a smaller diameter than the recess part, to hold the wafer by the chuck table with the interposition of the adhesive tape, and a cutting step of separating the recess part and the projection part by making a cutting blade that rotates cut into the wafer in such a manner that the cutting blade reaches the adhesive tape stuck to the recess part and rotating the chuck table in a state in which the projection part is not fixed.

Preferably, the wafer is supported by an annular frame through the adhesive tape in the tape sticking step, and the cutting blade is made to cut into the wafer in the state in which the projection part and the frame are not fixed in the cutting step.

In the cutting method of a wafer according to the aspect of the present invention, the cutting blade is made to cut into the wafer, and the recess part (central part) and the projection part (outer circumferential part) are separated in the state in which the projection part (outer circumferential part) of the wafer is not fixed. Due to this, the stress on the wafer at the time of the cutting is reduced, and the occurrence of a processing defect is suppressed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view illustrating a front surface side of a wafer;

FIG. 1B is a perspective view illustrating a back surface side of the wafer;

FIG. 2A is a perspective view illustrating the wafer to which an adhesive tape is stuck;

FIG. 2B is a sectional view illustrating the wafer to which the adhesive tape is stuck;

FIG. 3 is a perspective view illustrating a cutting apparatus;

FIG. 4 is a sectional view illustrating the wafer held by a chuck table;

FIG. 5A is a perspective view illustrating the wafer in a state in which a cutting blade cuts into the wafer;

FIG. 5B is a sectional view illustrating the wafer in the state in which the cutting blade cuts into the wafer;

FIG. 6 is an enlarged sectional view illustrating an outer circumferential part of the wafer;

FIG. 7A is a perspective view illustrating the wafer when the chuck table rotates;

FIG. 7B is a sectional view illustrating the wafer when the chuck table rotates; and

FIG. 8 is a graph illustrating a measurement result of a chipping size.

### DETAILED DESCRIPTION OF THE PREFERRED EMBODIMENT

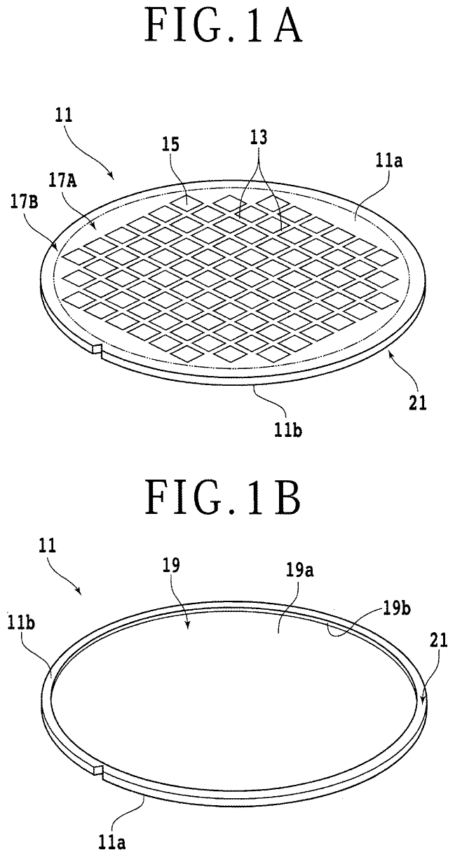

An embodiment according to the aspect of the present invention will be described below with reference to the accompanying drawings. First, a configuration example of a wafer that can be processed by a cutting method of a wafer according to the present embodiment will be described. FIG. 1A is a perspective view illustrating a front surface side of a wafer 11. FIG. 1B is a perspective view illustrating a back surface side of the wafer 11.

For example, the wafer 11 is a substrate that is composed of a semiconductor such as silicon and has a circular disc shape and includes a front surface 11a and a back surface 11b substantially parallel to each other. The wafer 11 is segmented into multiple rectangular regions by multiple streets (planned dividing lines) 13 arranged in a lattice manner to intersect each other. Furthermore, a device 15 such as an integrated circuit (IC), large scale integration (LSI), a light emitting diode (LED), or micro electro mechanical systems (MEMS) device is formed on the side of the front surface 11a in each of the regions marked out by the streets 13. The wafer 11 includes, on the side of the front surface 11a, a substantially circular device region 17A in which the multiple devices 15 are formed and an annular outer circumferential surplus region 17B that surrounds the device region 17A. The outer circumferential surplus region 17B is corresponding to an annular region that includes the outer circumferential edge of the front surface 11a and has a predetermined width (for example, approximately 2 mm). In FIG. 1A, a boundary between the device region 17A and the outer circumferential surplus region 17B is depicted by a two-dot chain line. There is no limit on the material, a shape, a structure, a size, and so forth of the wafer 11. For example, the wafer 11 may be a substrate composed of a semiconductor other than silicon (GaAs, InP, GaN, SiC, or the like), glass, ceramic, resin, metal, or the like. Furthermore, there is no limit also on the kind, a quantity, a shape, a structure, a size, an arrangement, and so forth of the devices 15.

Multiple device chips each including the device 15 are manufactured by dividing of the wafer 11 in a lattice manner along the streets 13. Furthermore, the device chips with a reduced thickness are obtained by executing of thinning treatment for the wafer 11 before dividing. For the thinning of the wafer 11, a grinding apparatus is used, for example. The grinding apparatus includes a chuck table (holding table) that holds a workpiece and a grinding unit that executes grinding processing for the workpiece, and a grinding wheel including grinding abrasive stones is mounted on the grinding unit. When the wafer 11 is held by the chuck table and the grinding abrasive stones are brought into contact with the side of the back surface 11b of the wafer 11 while the chuck table and the grinding wheel are each rotated, the side of the back surface 11b of the wafer 11 is ground, and the wafer 11 is thinned. However, when the whole of the side of the back surface 11b of the wafer 11 is ground, the whole of the wafer 11 is thinned and the rigidity of the wafer 11 lowers, and subsequent handling (conveyance, holding, and so forth) of the wafer 11 becomes difficult. Thus, the thinning treatment (grinding processing) is executed for only a partial region on the side of the back surface 11b of the wafer 11 in some cases.

For example, only a central part is ground and thinned in the wafer 11. In this case, as illustrated in FIG. 1B, a circular recess part (groove) 19 is formed in the back surface 11b of the wafer 11. The recess part 19 is made at a position corresponding to the device region 17A. Specifically, the size (diameter) of the recess part 19 is set substantially the same as the size (diameter) of the device region 17A, and the recess part 19 is formed at a position that overlaps with the device region 17A. The recess part 19 includes a circular bottom surface 19a substantially parallel to the front surface 11a and the back surface 11b of the wafer 11 and an annular side surface (inner wall) 19b that is substantially parallel to the thickness direction of the wafer 11 and is connected to the back surface 11b and the bottom surface 19a. Furthermore, an annular projection part (reinforcing part) 21 corresponding to the region for which the thinning treatment (grinding processing) has not been executed remains at the outer circumferential part of the wafer 11. The projection part 21 includes the outer circumferential surplus region 17B and surrounds the device region 17A and the recess part 19. When only the central part of the wafer 11 is thinned, the outer circumferential part (projection part 21) of the wafer 11 is kept at the thick state. Due to this, the lowering of the rigidity of the wafer 11 is suppressed and deformation, breakage, and so forth of the wafer 11 in handling of the wafer 11 become less likely to occur. That is, the projection part 21 functions as a reinforcing region that reinforces the wafer 11.

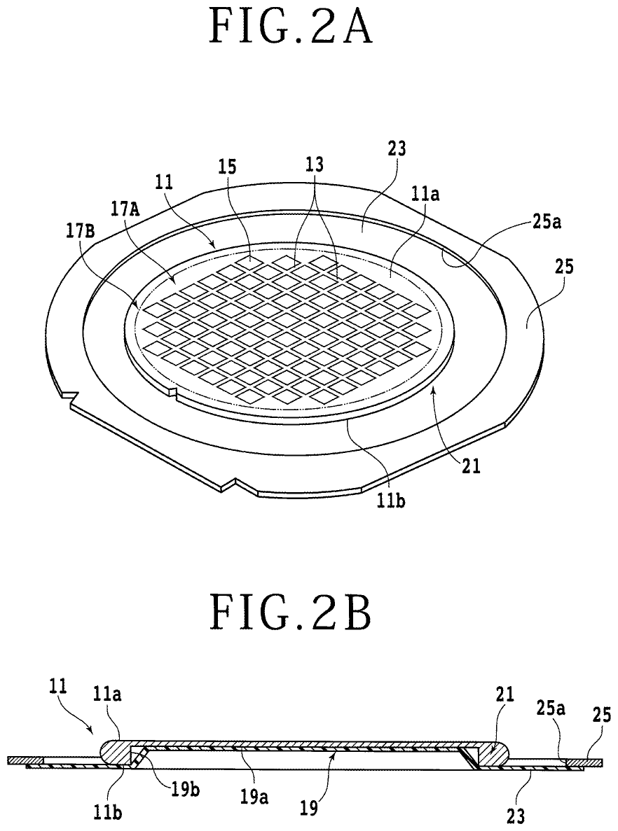

Next, a specific example of the cutting method of a wafer for dividing the wafer 11 having the recess part 19 into multiple device chips will be described. In the present embodiment, first, an adhesive tape is stuck to the wafer 11 (tape sticking step). FIG. 2A is a perspective view illustrating the wafer 11 to which an adhesive tape 23 is stuck. FIG. 2B is a sectional view illustrating the wafer 11 to which the adhesive tape 23 is stuck.

The adhesive tape 23 with a size that allows covering of the whole of the side of the back surface 11b of the wafer 11 is stuck to the side of the back surface 11b of the wafer 11. For example, the adhesive tape 23 having a circular shape with a larger diameter than the wafer 11 is stuck to the side of the back surface 11b of the wafer 11 to cover it. As the adhesive tape 23, a flexible film including a circular base and an adhesive layer (glue layer) made on the base can be used. For example, the base is composed of a resin such as polyolefin, polyvinyl chloride, or polyethylene terephthalate and the adhesive layer is composed of an epoxy-based, acrylic-based, or rubber-based adhesive, or the like. Furthermore, it is also possible to use an ultraviolet-curable resin that is cured by irradiation with ultraviolet rays as the adhesive layer. The adhesive tape 23 is stuck along the contour of the side of the back surface 11b of the wafer 11. That is, as illustrated in FIG. 2B, the adhesive tape 23 is stuck along (in line with) the bottom surface 19a and the side surface 19b of the recess part 19 and the back surface (lower surface) of the projection part 21. In FIG. 2B, the case is illustrated in which a slight gap (space) exists between the bottom surface 19a and the side surface 19b and the adhesive tape 23 at the outer circumferential part of the recess part 19. However, the adhesive tape 23 may be stuck to be in close contact with the bottom surface 19a and the side surface 19b.

An annular frame 25 made of a metal such as stainless steel (SUS) is stuck to the outer circumferential part of the adhesive tape 23. A circular opening 25a that penetrates the frame 25 in the thickness direction is made at the central part of the frame 25. The diameter of the opening 25a is larger than that of the wafer 11. Furthermore, the central part of the adhesive tape 23 is stuck to the side of the back surface 11b of the wafer 11 disposed inside the opening 25a and the outer circumferential part of the adhesive tape 23 is stuck to the frame 25. Thereby, the wafer 11 is supported by the frame 25 through the adhesive tape 23 and a frame unit (workpiece set) in which the wafer 11, the adhesive tape 23, and the frame 25 are integrated is configured.

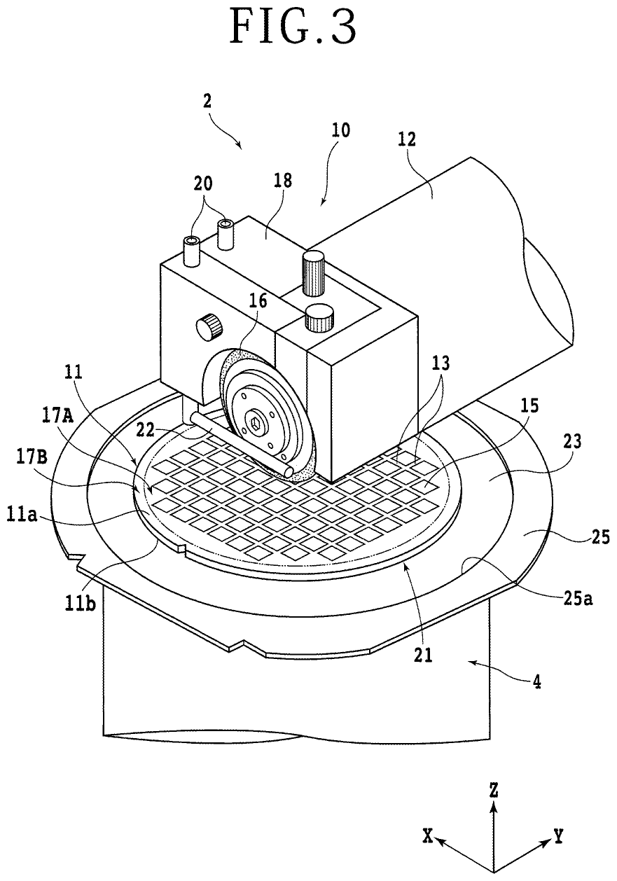

The wafer 11 to which the adhesive tape 23 is stuck is cut by the cutting apparatus. FIG. 3 is a perspective view illustrating a cutting apparatus 2. In FIG. 3, an X-axis direction (processing feed direction, first horizontal direction) and a Y-axis direction (indexing feed direction, second horizontal direction) are directions perpendicular to each other. Furthermore, a Z-axis direction (vertical direction, upward-downward direction, height direction) is the direction perpendicular to the X-axis direction and the Y-axis direction. The cutting apparatus 2 includes a chuck table (holding table) 4 that holds the wafer 11 and a cutting unit 10 that cuts the wafer 11 held by the chuck table 4.

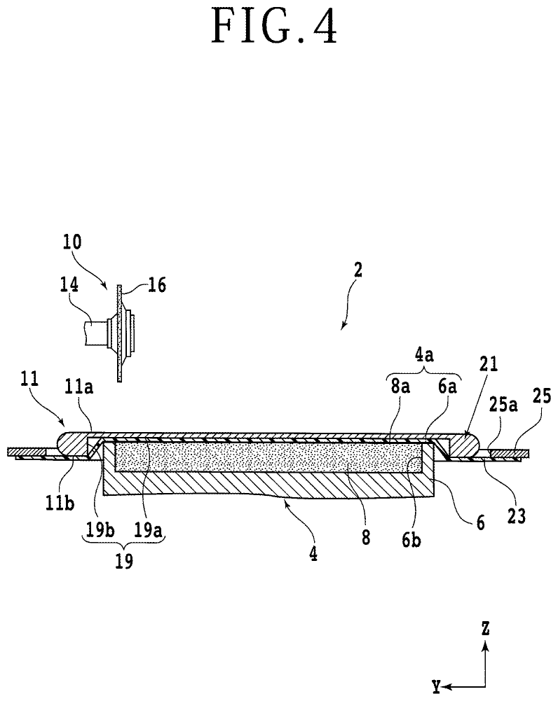

The upper surface of the chuck table 4 is a flat surface substantially parallel to the horizontal direction (XY-plane direction) and configures a circular holding surface 4a (see FIG. 4) that holds the wafer 11. Furthermore, to the chuck table 4, a movement mechanism (not illustrated) of a ball screw system that moves the chuck table 4 along the X-axis direction and a rotational drive source (not illustrated) such as a motor that rotates the chuck table 4 around a rotation axis substantially parallel to the Z-axis direction are coupled.

The cutting unit 10 is disposed over the chuck table 4. The cutting unit 10 includes a cylindrical housing 12 and a circular column-shaped spindle 14 (see FIG. 4) disposed along the Y-axis direction is housed in the housing 12. The tip part (one end part) of the spindle 14 is exposed to the external of the housing 12 and a rotational drive source such as a motor is coupled to the base end part (the other end part) of the spindle 14. An annular cutting blade 16 is mounted on the tip part of the spindle 14. The cutting blade 16 rotates at a predetermined rotation speed around a rotation axis substantially parallel to the Y-axis direction by power transmitted from the rotational drive source through the spindle 14.

As the cutting blade 16, a hub-type cutting blade (hub blade) is used, for example. The hub blade is configured with integration of an annular base composed of a metal or the like and an annular cutting edge formed along the outer circumferential edge of the base. The cutting edge of the hub blade is configured by an electroformed abrasive stone in which abrasive grains composed of diamond or the like are fixed by a binder such as a nickel plating layer. However, it is also possible to use a washer-type cutting blade (washer blade) as the cutting blade 16. The washer blade is configured by only an annular cutting edge in which abrasive grains are fixed by a binder composed of a metal, a ceramic, a resin, or the like.

The cutting blade 16 mounted in the cutting unit 10 is covered by a blade cover 18 fixed to the housing 12. The blade cover 18 includes a pair of connecting parts 20 connected to a tube (not illustrated) to which liquid (cutting liquid) such as purified water is supplied and a pair of nozzles 22 that are connected to the pair of connecting parts 20 and are each disposed on a respective one of two surface sides (front and back surface sides) of the cutting blade 16. A supply port (not illustrated) opened toward the cutting blade 16 is formed in each of the pair of nozzles 22. When being supplied to the connecting parts 20, the cutting liquid flows into the pair or nozzles 22 and is supplied from the supply ports of the pair of nozzles 22 toward both surfaces (front and back surfaces) of the cutting blade 16. By this cutting liquid, the wafer 11 and the cutting blade 16 are cooled, and dust generated due to the cutting processing (cutting dust) is washed off.

A movement mechanism (not illustrated) of a ball screw system is coupled to the cutting unit 10. The movement mechanism moves the cutting unit 10 along the Y-axis direction and the Z-axis direction. By the movement mechanism, the position of the cutting blade 16 in the indexing feed direction, a depth of cutting-in of the cutting blade 16 into the wafer 11, and so forth are adjusted.

When the wafer 11 is processed by the cutting apparatus 2, first, the wafer 11 is held by the chuck table 4 with the interposition of the adhesive tape 23 (holding step). FIG. 4 is a sectional view illustrating the wafer 11 held by the chuck table 4.

The chuck table 4 includes a frame body (main body part) 6 that is composed of a metal such as a SUS, glass, ceramic, resin, or the like and has a circular column shape. A recess part (groove) 6b with a circular column shape is formed on the side of an upper surface 6a of the central part of the frame body 6, and a holding component 8 with a circular disc shape is fitted into the recess part 6b. The holding component 8 is a component composed of a porous material such as a porous ceramic and internally includes pores (flow path) that communicate from the upper surface of the holding component 8 to the lower surface. The holding component 8 is connected to a suction source (not illustrated) such as an ejector through a flow path (not illustrated) formed inside the frame body 6, a valve (not illustrated), and so forth. Furthermore, the upper surface of the holding component 8 configures a circular suction surface 8a that sucks the wafer 11. The upper surface 6a of the frame body 6 and the suction surface 8a of the holding component 8 are disposed on substantially the same plane and configure the holding surface 4a of the chuck table 4.

The wafer 11 is disposed over the chuck table 4 with the side of the front surface 11a exposed upward. The chuck table 4 is configured to be capable of holding the bottom surface 19a of the recess part 19 of the wafer 11 by the holding surface 4a. Specifically, the diameter of the holding surface 4a is smaller than that of the recess part 19. Furthermore, when the wafer 11 is disposed over the chuck table 4, the side of the holding surface 4a of the chuck table 4 is fitted into the recess part 19. Thereby, the bottom surface 19a of the recess part 19 is supported by the holding surface 4a with the interposition of the adhesive tape 23. When a negative pressure (suction force) of the suction source is caused to act on the holding component 8 in the state in which the wafer 11 is disposed over the chuck table 4, the region stuck to the bottom surface 19a of the recess part 19 in the adhesive tape 23 is sucked by the suction surface 8a. Thereby, the wafer 11 is sucked and held by the chuck table 4 with the interposition of the adhesive tape 23. When the wafer 11 is disposed over the holding surface 4a in the state in which a suction force does not act on the suction surface 8a, the wafer 11 becomes the state in which it bends in a manner projecting upward due to the own weight of the projection part 21 of the wafer 11 in some cases. However, when a suction force is caused to act on the suction surface 8a, the bottom surface 19a of the recess part 19 is flatly supported along the holding surface 4a. As a result, the bending of the wafer 11 is corrected, and the wafer 11 becomes the state in which the whole of the wafer 11 is substantially flat.

Here, a component (part of the chuck table 4, another holding component, or the like) that holds the wafer 11, the adhesive tape 23, or the frame 25 is not disposed in the region outside in the radial direction of the holding surface 4a relative to the outer circumferential edge of the holding surface 4a of the chuck table 4. Thus, when the wafer 11 is held by the chuck table 4, the projection part 21 of the wafer 11, the outer circumferential part of the adhesive tape 23, and the frame 25 are not fixed and become a suspended state. However, the cutting apparatus 2 often includes multiple clamps (not illustrated) that are disposed around the chuck table 4 and grasp and fix the frame 25. In this case, in the holding step and a cutting step to be described later, the state in which the frame 25 is released without being grasped by the clamps is made.

Next, the wafer 11 is cut by the cutting blade 16 and the recess part 19 and the projection part 21 of the wafer 11 are separated (cutting step). In the cutting step, the wafer 11 is annularly cut by rotating the chuck table 4 in the state in which the cutting blade 16 is made to cut into the wafer 11. In the cutting step, the projection part 21 of the wafer 11, the outer circumferential part of the adhesive tape 23, and the frame 25 are not fixed but kept at the suspended state (see FIG. 4).

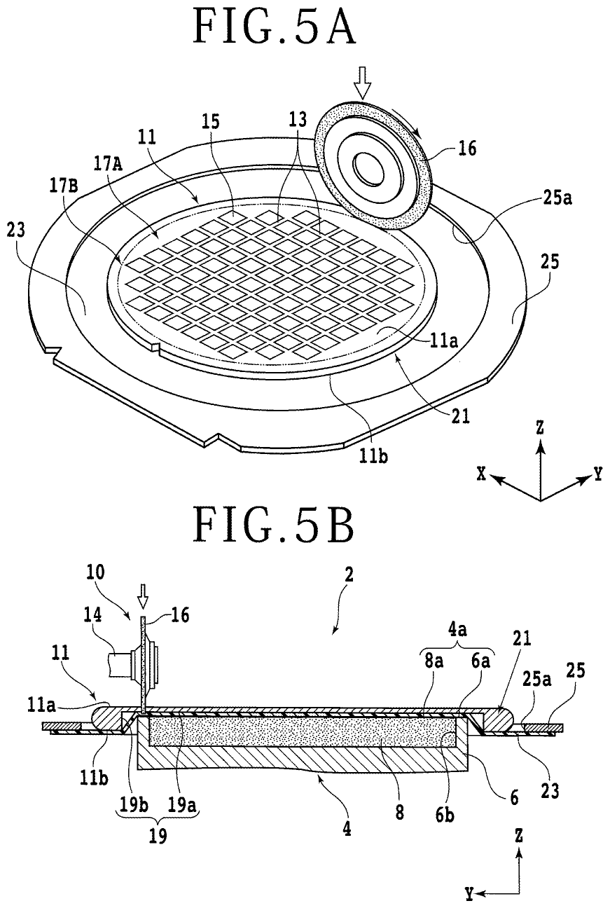

First, the cutting blade 16 that rotates is made to cut into the wafer 11. FIG. 5A is a perspective view illustrating the wafer 11 in the state in which the cutting blade 16 cuts into the wafer 11. FIG. 5B is a sectional view illustrating the wafer 11 in the state in which the cutting blade 16 cuts into the wafer 11. When the cutting blade 16 is made to cut into the wafer 11, the chuck table 4 is disposed below the cutting unit 10. Then, the positions of the chuck table 4 and the cutting unit 10 are adjusted to cause the cutting blade 16 to overlap with the outer circumferential part of the recess part 19 of the wafer 11. Next, the cutting unit 10 is lowered toward the chuck table 4 while the cutting blade 16 is rotated. Thereby, the cutting blade 16 cuts into the side of the front surface 11a of the wafer 11. Then, the cutting unit 10 lowers until the lower end of the cutting blade 16 reaches the adhesive tape 23 stuck to the bottom surface 19a of the recess part 19. A difference in a height between the front surface 11a of the wafer 11 and the lower end of the cutting blade 16 at this time corresponds to the depth of the cutting-in of the cutting blade 16 into the wafer 11.

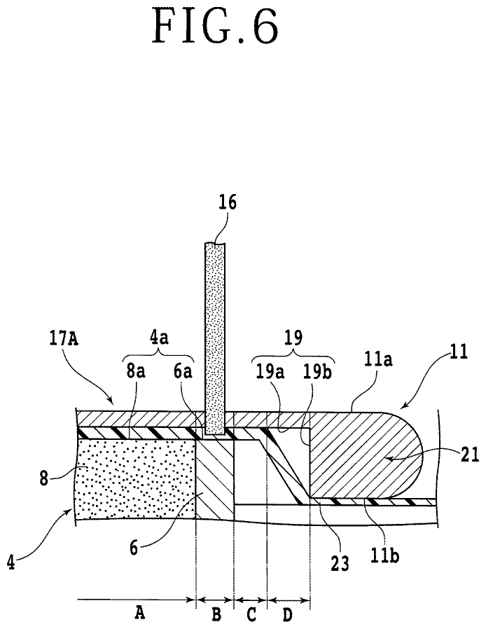

FIG. 6 is an enlarged sectional view illustrating the outer circumferential part of the wafer 11. Regions A to D that overlap with the recess part 19 of the wafer 11 are included in the wafer 11. The region A is a region that overlaps with the suction surface 8a of the holding component 8. The region B is a region that overlaps with the upper surface 6a of the frame body 6. The regions C and D are regions that do not overlap with the holding surface 4a. Furthermore, the region C is a region that overlaps with a region in which the bottom surface 19a of the recess part 19 is in contact with the adhesive tape 23. The region D is a region that overlaps with a region in which the bottom surface 19a of the recess part 19 is not in contact with the adhesive tape 23 (gap between the bottom surface 19a and the side surface 19b and the adhesive tape 23). For example, the cutting blade 16 cuts into the region B of the wafer 11. Due to this, the region surely supported by the frame body 6 in the wafer 11 can be cut while the device region 17A with a large area is reserved at the central part of the wafer 11. However, it is also possible to make the cutting blade 16 cut into the region A, the region C, or the region D.

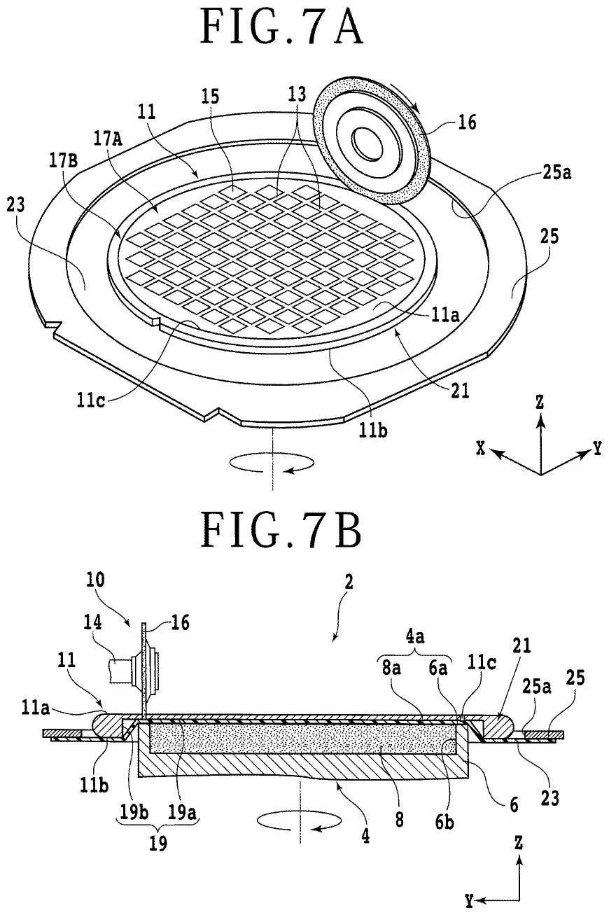

Next, the chuck table 4 is rotated while the cutting blade 16 is rotated. FIG. 7A is a perspective view illustrating the wafer 11 when the chuck table 4 rotates. FIG. 7B is a sectional view illustrating the wafer 11 when the chuck table 4 rotates. When one revolution of the chuck table 4 is made in the state in which the cutting blade 16 cuts into the wafer 11, the wafer 11 is annularly cut. As a result, an annular kerf (cut) 11c that reaches the bottom surface 19a of the recess part 19 from the front surface 11a of the wafer 11 is formed in the vicinity of the boundary between the device region 17A and the outer circumferential surplus region 17B. As a result, the central part (recess part 19) and the outer circumferential part (projection part 21) of the wafer 11 are separated.

In the cutting of the wafer 11 by the cutting blade 16, if the projection part 21 of the wafer 11 is fixed to a specific position, the wafer 11 often bends unintentionally due to an error in a positional relation between the holding surface 4a of the chuck table 4 and the position to which the projection part 21 is fixed. In this case, stress acts on the wafer 11, and a processing defect such as chipping (breakage) becomes more likely to occur when the cutting blade 16 is made to cut into the wafer 11. On the other hand, in the present embodiment, when the cutting step is executed, the projection part 21 of the wafer 11, the outer circumferential part of the adhesive tape 23, and the frame 25 are not fixed but kept at the suspended state. Thus, unintentional bending of the wafer 11 that possibly occurs when the projection part 21 is fixed to a specific position is avoided. Furthermore, when the cutting blade 16 gets contact with the wafer 11, the projection part 21 can get slightly displaced according to the load applied to the wafer 11. Due to this, the stress on the wafer 11 is reduced compared with the case in which the projection part 21 is fixed. As a result, the occurrence of a processing defect when the wafer 11 is cut by the cutting blade 16 is suppressed.

When the annular projection part 21 separated from the wafer 11 has been removed, the thinned device region 17A remains over the chuck table 4. Thereafter, for example, by cutting the wafer 11 along the streets 13 by the cutting blade 16 to divide the wafer 11, multiple device chips each including the device 15 are obtained.

As described above, in the cutting method of a wafer according to the present embodiment, the cutting blade 16 is made to cut into the wafer 11, and the recess part 19 and the projection part 21 are separated in the state in which the projection part 21 of the wafer 11 is not fixed. Due to this, the stress on the wafer 11 at the time of the cutting is reduced, and the occurrence of a processing defect is suppressed.

Structures, methods, and so forth according to the above-described embodiment can be carried out with appropriate changes without departing from the range of the object of the present invention.

### Working Example

Next, description will be made about a result of evaluating wafers cut by using the cutting method of a wafer according to the present invention. In the present working example, the wafers 11 according to a comparative example cut by the cutting blade 16 in the state of being held by the conventional method and the wafers 11 according to the working example cut by the cutting blade 16 in the state of being held by the method according to the present invention were observed and compared.

As the wafers 11, 8-inch silicon wafers (thickness was 0.725 mm) were used. Thinning treatment (grinding processing) was executed for the wafers 11 in advance, and the recess parts 19 were formed (see FIG. 1B and so forth). The recess part 19 was formed in such a manner that the annular projection part (reinforcing part) 21 with a width of 2.1 mm remained at the outer circumferential part of the wafer 11 and the thickness of the wafer 11 in the device region 17A became 0.1 mm. Four wafers were prepared as the above-described wafers 11, and two wafers were used as the wafers according to the comparative example (wafers A1 and A2) while the remaining two wafers were used as the wafers according to the working example (wafers B1 and B2).

Next, the adhesive tape 23 was stuck to each of the wafers A1, A2, B1, and B2 (see FIG. 2A and FIG. 2B). Thereafter, the wafers A1, A2, B1, and B2 were each cut by the cutting apparatus 2 (see FIG. 3).

The wafers A1 and A2 according to the comparative example were held by the conventional method and were cut. Specifically, the bottom surface 19a of the recess part 19 of the wafer A1 or A2 was held by the holding surface 4a of the chuck table 4 (see FIG. 4). Furthermore, an annular support component (spacer) that supported the lower surface side of the projection part 21 of the wafer A1 or A2 was set outside the holding surface 4a of the chuck table 4 and the projection part 21 was held by the upper surface (holding surface) of the support component. The holding surface of the support component was positioned on the lower side relative to the holding surface 4a of the chuck table 4 and the difference in the height between the holding surface 4a and the holding surface of the support component was adjusted to the depth of the recess part 19. Then, the region stuck to the lower surface side of the projection part 21 in the adhesive tape 23 was held under suction by the holding surface of the support component. That is, the wafers A1 and A2 according to the comparative example were set to the state in which the bottom surface 19a of the recess part 19 and the projection part 21 were held.

On the other hand, the wafers B1 and B2 according to the working example were held by the method according to the present invention and were cut. Specifically, as illustrated in FIG. 4, the bottom surface 19a of the recess part 19 of the wafer B1 or B2 was held by the holding surface 4a of the chuck table 4 and the projection part 21 of the wafer B1 or B2 was not held but set to a suspended state.

Next, the wafers A1, A2, B1, and B2 were each cut by the cutting blade. Specifically, first, the cutting blade 16 was made to cut into the wafer A1, A2, B1, or B2 (see FIG. 5A and FIG. 5B). The cutting blade 16 was made to cut into a region that overlaps with the frame body 6 of the chuck table 4 (region B in FIG. 6). Furthermore, the rotation speed of the cutting blade 16 (rotation speed of the spindle 14) was set to 30000 rpm. Thereafter, one revolution of the chuck table 4 was made with the rotation of the cutting blade 16 kept, to annularly cut the wafer A1, A2, B1, or B2 (see FIG. 7A and FIG. 7B). The rotation speed of the chuck table 4 was set to a low speed (3 deg/s) when the wafer A1 according to the comparative example and the wafer B1 according to the working example were cut. On the other hand, the rotation speed of the chuck table 4 was set to a high speed (15 deg/s) when the wafer A2 according to the comparative example and the wafer B2 according to the working example were cut.

Then, major eight chippings (breakage) that remained on the side of the bottom surface 19a of the wafers A1, A2, B1, and B2 after the cutting were observed and the size of the chippings was measured.

Specifically, the length of the chippings that had developed from the kerf 11c (see FIG. 7A and FIG. 7B) along the bottom surface 19a in the direction perpendicular to the kerf 11c (radial direction of the wafer) was measured as the chipping size. Furthermore, from the measured size of the eight chippings, the maximum value of the chipping size (maximum chipping size) and the average value thereof (average chipping size) were calculated.

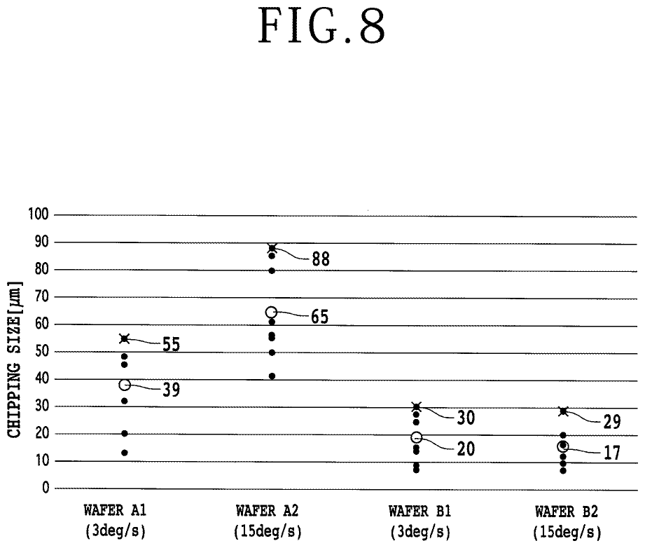

FIG. 8 is a graph illustrating the measurement result of the chipping size. Dots (black circle marks), cross marks, and white circle marks in the graph indicate the chipping size, the maximum chipping size, and the average chipping size, respectively. As illustrated in FIG. 8, when the wafers A1 and B1 cut with the rotation speed of the chuck table 4 set to the low speed (3 deg/s) were compared, the maximum chipping size was reduced from 55 to 30 μm and the average chipping size was reduced from 39 to 20 μm by cutting the wafers by the cutting method according to the present invention. Furthermore, when the wafers A2 and B2 cut with the rotation speed of the chuck table 4 set to the high speed (15 deg/s) were compared, the maximum chipping size was reduced from 88 to 29 μm and the average chipping size was reduced from 65 to 17 μm.

In the past, it is considered that it is preferable to cut the wafer 11 in the state in which both the recess part 19 and the projection part 21 of the wafer 11 are held in order to cut the wafer 11 having the recess part 19 without causing the occurrence of a processing defect. However, from the above-described result, it has been confirmed that the stress on the wafer 11 is effectively reduced and the size of the chipping is significantly reduced when the wafer 11 is cut in the state in which the projection part 21 is not fixed but suspended. Furthermore, when the wafer 11 was held by the conventional method, there was a tendency that the size of the chipping increased although the processing time became shorter with the rise of the rotation speed of the chuck table 4 (see wafers A1 and A2). On the other hand, when the wafer 11 was cut in the state in which the projection part 21 was not fixed but suspended, increase in the size of the chipping was not found even with the rise of the rotation speed of the chuck table 4 (see wafers B1 and B2). Due to this, it has been confirmed that the cutting method of a wafer according to the present invention is remarkably effective also for increase in the processing feed rate.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting method of a wafer for cutting the wafer that includes a circular recess part at a central part and includes an annular projection part surrounding the recess part at an outer circumferential part, the cutting method comprising:
a tape sticking step of sticking an adhesive tape along the recess part and the projection part;
a holding step of sucking the adhesive tape stuck to the recess part by a holding surface of a chuck table having the holding surface with a smaller diameter than the recess part to hold the wafer by the chuck table with interposition of the adhesive tape; and
a cutting step of separating the recess part and the projection part by making a cutting blade that rotates cut into the wafer in such a manner that the cutting blade reaches the adhesive tape stuck to the recess part and rotating the chuck table in a state in which the projection part is not fixed.

2. The cutting method of a wafer according to claim 1, wherein
the wafer is supported by an annular frame through the adhesive tape in the tape sticking step, and
the cutting blade is made to cut into the wafer in a state in which the projection part and the frame are not fixed in the cutting step.
